(19) United States
(12) Patent Application Publication
(10) Pub. No.: US 2025/0324531 A1
(43) Pub. Date: Oct. 16, 2025

(54) CONNECTION DEVICE FOR PROVIDING A DECENTRALIZED AUTOMATION PLATFORM

(71) Applicants: Luca Hoffmann, Backnang (DE); Olaf Prein, Lügde-Rischenau (DE); Heiko Feisst, Schlierbach (DE); Tim Roolf, Backnang (DE)

(72) Inventors: Luca Hoffmann, Backnang (DE); Olaf Prein, Lügde-Rischenau (DE); Heiko Feisst, Schlierbach (DE); Tim Roolf, Backnang (DE)

(21) Appl. No.: 19/170,841

(22) Filed: Apr. 4, 2025

(30) Foreign Application Priority Data
Apr. 12, 2024 (DE) DE102024110296.9

(51) Int. Cl. H05K 7/14; G05B 15/02; G05B 19/418

(52) U.S. Cl. CPC H05K 7/1417; G05B 15/02; G05B 19/41805

(57) ABSTRACT

The invention relates to a connection device for a decentralized automation platform, comprising: a set of main and secondary connections for electrically connecting multiple functional modules in a connection area; one or more main connection surfaces with main connections; at least one guide surface positioned at a defined angle to the main connection surface to mechanically guide and support module assembly; a base body with a housing and a connection arrangement electrically linked to the main and/or secondary connections to interconnect the functional modules; and electrical lines within the housing to supply main energy, auxiliary energy, and data flow to operate the automation platform for controlling industrial plant devices.

### RELATED APPLICATIONS

This application claims the benefit of German Application DE, 10 2024 110 296.9 (filed on Apr. 12, 2024), the entirety of which is incorporated by reference herein

### FIELD OF THE INVENTION

The present invention relates to a connection device for providing a decentralized automation platform. Furthermore, the invention relates to an automation platform with the connecting device, a functional module and a method for operating a connecting device.

### BACKGROUND

It is known from the state of the art that modular automation solutions are used to supply electrical devices in an industrial plant with energy via power lines and to control them via control lines, such as fieldbus lines. Modularity is often achieved by using individual, independent functional modules that can be individually configured and combined. This has the advantage that the automation solutions can be flexibly adapted to the respective requirements of the industrial plant, thus ensuring a high level of efficiency and cost-effectiveness.

The publication US 2013/0342152 A1 discloses a multi-shaft motor drive device in which at least one amplifier module, a control substrate and a power substrate are provided.

The publications WO 2012/000808 A1, WO 2023/088883 A1 and EP 2 728 673 B1 disclose further solutions within the same category.

It is often a problem with conventional solutions that the assembly of functional modules of an automation platform can be time-consuming and error-prone. It is therefore a task of the present invention to at least partially eliminate the disadvantages described above. In particular, it is a task of the present invention to improve the connection of functional modules with a common connection device.

### SUMMARY OF THE INVENTION

The subject of the invention is a connecting device having the features of claim 1, an automation platform having the features of claim 13, a method having the features of claim 14 and a functional module having the features of claim 15. Further features and details of the invention are apparent from the respective subclaims, the description and the drawings.

Features and details that are described in connection with the connecting device according to the invention naturally also apply in connection with the automation platform according to the invention, the method according to the invention and the functional module according to the invention, and vice versa in each case, so that reference is or can always be made to the individual aspects of the invention reciprocally with regard to the disclosure.

The object of the invention is, in particular, a connection device for providing a decentralized automation platform. In particular, the connection device according to the invention has an arrangement of one or more main and secondary connections, which are provided for the electrical connection of one or more functional modules in a connection area of the connection device.

A decentralized automation platform can be understood as at least one piece of hardware, possibly with associated software, to automate certain processes in an electrical plant and/or system. For example, motors, preferably servomotors, are controlled and used to move a robot arm or control a conveyor belt. The connection device can be (at least) part of the automation platform in order to connect the multiple functional modules to it and/or to each other, and in this way provide various modular functions for automation, such as controlling the motors. This can have the advantage of enabling the connection device with the functional modules to connect and/or control and/or evaluate a large number of devices and components in an electrical system/plant in order to ensure smooth and efficient automation.

The automation platform can be decentralized in that it provides automation functions for the system/plant with one or more other decentralized automation platforms. The one or more further decentralized automation platforms can also each be designed as an automation platform according to the invention. The automation platforms can provide corresponding partial automation functions, which enable the automation of the system/plant in a complementary manner. The partial automation functions include, for example, control and/or regulation of variables such as pressure, flow or temperature and/or monitoring of process parameters and/or control and/or evaluation of actuators and sensors.

It is possible that the individual different partial automation functions are provided by functional modules designed for this purpose. In this way, partial automation functions can be supplemented and combined on a modular basis in an automation platform. The functional modules include, for example, a power supply module, such as a power supply unit, and/or a fieldbus module and/or a safety module for monitoring and safeguarding processes and/or a motor control module and/or an industrial PC, which can take over control tasks. In addition, pneumatic and/or hydraulic modules can also be provided as functional modules, for example to control movements and forces. These modules can, for example, be designed to control cylinders, valves and/or pumps These functional modules can also include cylinders, valves and/or pumps. By combining electronic and pneumatic/hydraulic elements, complex and precise control tasks can be realized in various application areas, such as automation technology.

It is also conceivable that the automation platforms are connected to a higher-level controller (central controller), e.g. via a fieldbus system. However, the decentralized automation platforms can at least partially replace the function of a central control cabinet. For this purpose, the automation platform can be arranged in the field of the system/plant, e.g. in the vicinity of actuators and sensors. This can have the advantage of achieving a high degree of flexibility and scalability of the automation, as further decentralized automation platforms can be added easily to provide additional automation functions. It is also possible that the decentralized design of the automation platforms makes the automation easier to maintain and more robust and failsafe, as failures of individual components can be compensated for by other decentralized automation platforms. This ensures a high level of automation availability.

A system/plant with decentralized automation platforms can also be protected.

Modularity can be achieved by designing the functional modules as individual modules, in particular independent modules, each with its own module housing and electronics that allow the modules to be individually configured and functionally combined with other functional modules. The functional modules can also have data and/or power supply interfaces to each other and/or to devices and/or components of the electrical system/plant. It is possible, for example, that at least one of the functional modules connected to the connection device is able to establish a wired and/or wireless connection to a device and/or component to be controlled. At least one of the functional modules connected to the connection device can also be designed to provide a power supply for a device to be controlled and/or a component and/or the other connected functional modules.

In the connection device according to the invention, furthermore, several or exactly one main connection surface can be provided, on which at least the main connections are arranged. This means in particular that the main connections are arranged essentially on one plane (main plane). The surface can, for example, be provided by a housing wall of the connection device.

Furthermore, at least one or exactly one guide surface can optionally be provided, which is arranged at a defined angle (W1) to the respective main connection surface in order to mechanically guide the functional modules into the connection area of the connection device and thus support assembly of the functional modules. The assembly can be provided for connecting (the functional modules) to the main and/or secondary connections and can include at least one manual assembly action such as inserting the functional modules into the connection area and/or fastening the functional modules. The guide surface can also be provided by a housing wall of the connection device. In particular, the secondary connections are arranged essentially on a plane that is at the defined angle W1 to the main plane or is inclined and/or runs parallel to a plane of the guide surface.

In addition, a base body with a base body housing and/or with a connection arrangement can optionally be provided with the connection device according to the invention. The connection arrangement can be electrically connected to the main and/or secondary connections in order to preferably (at least partially) provide an electrical connection for at least some of the connected functional modules to one another. The connection arrangement can be designed at least partially as an internal cabling and/or internal wiring and/or internal conductor track arrangement (e.g. by conductor tracks of at least one printed circuit board) of the connection device. “Internal” can refer to the arrangement of the connection arrangement within the basic body housing and/or other housing elements of the connection device.

The housing elements of the connection device, such as the basic body housing and housing walls, can be made of plastic, in particular a non-conductive plastic. The connection arrangement can be arranged partially or predominantly or completely inside the basic body housing.

Furthermore, it is possible that electrical lines of the connection arrangement are optionally provided, which can be arranged (partially or predominantly or completely) in the base body housing in order to provide a main energy flow and/or an auxiliary energy flow and/or a data flow for the connected functional modules. In this way, the automation platform can be reliably operated to control electrical devices in an industrial plant. The electrical lines can be designed as cables, printed conductors, flexible printed circuit boards or circuits, for example.

Within the scope of the invention, it may be provided that the main connections are arranged at a distance from each other in order to receive and hold one of the functional modules in a predefined position. For example, the main connections can be arranged in one direction (width direction) of the connection arrangement in order to accommodate the functional modules in this direction in a row and thus next to each other. The distance between the main connections in this direction can correspond at least to the width of the functional modules, i.e. the spatial extension of the functional modules in this direction.

It is also conceivable that the main connections each have at least one or at least two of the following connecting elements:
a main power connection element, also referred to as a main energy connection element, for providing the main energy flow for the functional module connected to it, in particular for the electrical energy supply of “first” electrical devices of the system/plant, preferably for motors,
an auxiliary power connection element, also referred to as an auxiliary energy connection element, for providing the auxiliary energy flow for the functional module connected thereto, in particular with a lower electrical voltage and/or lower electrical current than the main energy flow, preferably for the electrical energy supply of an electronic system (e.g. the functional module connected thereto) and/or of devices and/or components of the system/plant which have a lower energy consumption than the first electrical devices,
a data connection element for providing the data flow for the functional module connected to it.

In other words, the main connections can each have at least or exactly two connecting elements, in particular in the form of electrical connection elements. The secondary connections may also each have at least or exactly one connecting element, in particular in the form of an electrical connecting element.

Providing a main energy, auxiliary energy and/or data flow means in particular that the connected functional module can, but does not have to, tap the corresponding energy or data flow (the functional module does not necessarily have to contact the main energy connection element, for example, if it does not require the main energy flow).

The main power connection element, the auxiliary power connection element and the data connection element can be designed differently. For example, the connecting elements may differ in terms of their geometry and/or shape and/or surface and/or length and/or coding and/or electrical properties and/or the number of their contacts. The coding is in particular a coding for a connection and preferably a plug connection. This means that the coding is used to ensure the correct positioning and alignment of the connection and to prevent a faulty connection. To this end, the coding can, for example, have a specific shape that only permits a specific alignment of the connection. Alternatively, the coding can also be realized by a special colour coding or by a special arrangement of the contacts.

The connecting elements can be designed according to at least one of the following connection types: plug-in connection, socket, e.g. plug-in base, screw connection, spring clip connection, PCB contact. The connection type of the connecting elements of the main connections may differ from that or those of the secondary connections. The connecting elements of the main connections can also be designed according to the same or alternatively different connection types.

Of further advantage, it may be provided that the main ports each comprise the auxiliary power connection element and the data connection element, wherein the auxiliary ports may each comprise the main power connection element. In other words, the main connections can each be designed as an arrangement in which the two connection elements (auxiliary and data connection element) are provided at each of the main connections. The electrical lines of the connection arrangement are preferably electrically connected partly to the secondary connections and partly to the main connections within the main body housing.

According to an advantageous further development of the invention, it may be provided that the connection device further comprises: several or exactly one secondary connection surface, which is arranged at a further defined angle to the respective main connection surface, and on which the secondary connections are arranged. In other words, the secondary connections can enable a connection of the functional modules in a different axis and/or from a different direction and/or with a different housing side of the functional modules than the main connections. This can have the advantage that a more flexible arrangement of the functional modules within the connection device is possible. By using the secondary connections at a different angle to the main connections, the functional modules can also be placed in narrow or inaccessible areas without affecting the connection to other modules.

Advantageously, within the scope of the invention, it can be provided that the secondary connections are arranged on the at least one guide surface. It is thus possible for assembly to be simplified and safer, since a mechanical guide for the functional modules can support the assembly movement.

It is also advantageous if the secondary connections are oriented differently in relation to the main connections, in particular with a different angle, so that mechanical and/or electrical contact is made between the functional module and the main and secondary connections from different directions during assembly, preferably in more than one axis. The at least one guide surface can provide a mechanical guide in an insertion direction and/or in a width direction or horizontal direction of the connection device in order to support contact with the main connections in the insertion direction. The guide surface can also preferably limit movement of the functional modules during assembly in a direction other than the direction of insertion. This makes assembly easier and less prone to errors.

Furthermore, within the scope of the invention, it may be provided that the electrical lines of the connection arrangement comprise the following lines:
main power lines designed to provide the main energy flow with an AC voltage up to 1000 volts and/or with a DC voltage up to 1500 volts and/or with an AC voltage in the range of 70 volts to 1000 volts and/or with a DC voltage in the range of 130 volts to 1500 volts, and preferably with an AC voltage of substantially 400 volts or a DC voltage in the range of 650 V to 700 V, preferably to supply power to at least one of the electrical devices,
auxiliary power lines which are designed to provide the auxiliary energy flow with an AC voltage of up to 50 volts and/or a DC voltage of up to 120 volts and/or with an AC voltage in the range from 0.01 volts to 50 volts and/or with a DC voltage in the range from 0.01 volts to 120 volts, and preferably with a DC voltage of essentially 24 V or 48 V, preferably in order to provide a power supply for at least one of the functional modules and/or for communication with at least one of the electrical devices, preferably for a field bus,
data lines which are designed to transmit a data and preferably field bus signal, preferably for communication with at least one of the electrical devices.

The main power, auxiliary power and data cables can differ in terms of their cable diameter, for example, in order to be suitable for different electrical outputs. The main power and auxiliary power cables may include stranded conductors to ensure greater flexibility and pliability.

Optionally, it can be provided that the main power lines and the auxiliary power lines and/or data lines are arranged in separate channels of the base body and are preferably separated from each other by a partition wall (partition). This can have the advantage that better shielding against electromagnetic interference is achieved, since the main power lines and the auxiliary power lines and/or data lines run separately from each other. In addition, the partition wall can ensure greater safety by preventing the auxiliary power lines and/or data lines from being damaged in the event of a fault in the main power lines. In addition, the arrangement of the lines in separate ducts can facilitate maintenance and repair, as the affected lines can be identified and reached more easily.

According to a further advantage, it can be provided that the defined angle and preferably also the further defined angle are essentially 90 degrees, whereby preferably the respective guide surface is connected to the one or at least one of the main connection surfaces and can represent an extension of the respective main connection surface. This enables reliable guidance and provides a particularly stable housing structure.

It is also advantageous if contact is made between a connector arrangement of one of the functional modules, comprising a functional module main connector and a functional module secondary connector, and a connection arrangement of the base body, comprising one of the main connections and one of the secondary connections, in more than one axis. This can have the advantage of ensuring a stable and reliable connection between the functional modules and the base body. Multi-axis contacting also enables greater flexibility in the arrangement of the functional modules on the base body. It is also possible that a higher number of functional modules can be accommodated on the base body using multi-axis contacting, which leads to greater functionality of the overall system/plant.

According to an advantageous further development of the invention, it can be provided that the basic body housing is designed in several parts and forms the respective main connection surface and guide surface and, in particular, the secondary connection surface. Alternatively or additionally, the base body housing can be essentially L-shaped or U-shaped, whereby the parts of the base body housing can be connected to one another in a form-fitting and/or force-fitting manner. In this way, a particularly stable and easy-to-install automation platform can be provided.

It is also possible that the base body housing is designed in one piece and forms the respective main connection surface and guide surface and, in particular, the secondary connection surface, whereby the base body housing is essentially L-shaped or U-shaped. This enables a particularly simple and stable design of the connection device.

Advantageously, the invention may provide that at least one sealant (sealing means) is provided in the connection area in order to seal the connection area. By using a suitable sealant, improved functionality and durability of the device according to the invention can thus be achieved. It is also possible for the sealant to have a high temperature and chemical resistance in order to meet the requirements of the respective application. The sealant may be suitable for preventing the ingress of moisture, dust and dirt into the connection device in order to protect the electronics in the housing of the connection device. An example of such a sealant is silicone sealant, which is particularly advantageous due to its high elasticity and resistance to moisture and UV radiation. Another example is polyurethane as a sealant, which is suitable due to its high chemical resistance and its ability to adapt to uneven surfaces. Another possible sealant is epoxy resin, which is suitable due to its high strength, chemical resistance and electrical insulation properties. In addition, the shape of the sealant can be adapted to an external housing shape of the connection device and/or the functional modules. This makes it possible for the sealant to be seamlessly integrated into the housing shape, creating a smooth surface that enables easy cleaning and maintenance.

It is also possible that at least one receptacle for a fastening element, preferably for a screw, is provided. The receptacle, preferably a threaded hole, can be designed with an angle, preferably in the range of 10° to 80°, to the main connection surface in the base body housing in order to provide an angled fastening and preferably screw connection of the respective functional module to the base body housing. This can have the advantage that the functional module is securely and stably fastened. It is also possible that the receptacle for the fastening element is arranged in a recess in the basic body housing in order to ensure a flat and even main connection surface. This allows the functional module to be flush with the base body housing and, in particular, the connection surface and enables a compact design of the automation platform.

Another object of the invention is an automation platform comprising a connecting device according to the invention and the multiple functional modules. The automation platform according to the invention thus has the same advantages as those described in detail with reference to a connecting device according to the invention.

Another object of the invention can optionally be a plant and/or system for an industrial plant and/or an industrial plant which has at least two or at least four or at least six automation platforms. The respective automation platform can be decentralized in that it provides automation functions and preferably partial automation functions for the industrial plant together with the respective other automation platform or platforms. The respective automation platforms can be designed as automation platforms according to the invention.

The automation platforms can optionally each provide partial automation functions that enable the automation of the system/plant in a complementary manner (i.e. in relation to the joint provision of the partial automation functions by all automation platforms). The partial automation functions include, for example, control and/or regulation of variables such as pressure, flow or temperature and/or monitoring of process parameters and/or control and/or evaluation of actuators and sensors.

Another object of the invention is a method for manufacturing and/or operating a connection device, in particular according to the invention, for providing a decentralized automation platform.

According to a first step, the method may comprise providing an arrangement of a plurality of main and secondary connections, wherein the main and secondary connections may be provided for electrically connecting a plurality of functional modules in a connection area of the connection device.

The method according to a further step may further comprise: Providing several or exactly one main connection surface on which at least the main connections are arranged. For this purpose, the main connection surface can be provided, for example, by a housing wall which has recesses in which corresponding main connections are provided.

The method according to a further step may further comprise Providing at least one guide surface, which is arranged at a defined angle to the respective main connection surface, in order to mechanically guide the functional modules into the connection area and thus support an assembly of the functional modules, which is provided for connection to the main and/or secondary connections. The guide surface can be provided, for example, by a housing wall that extends at a defined angle from the housing wall that forms the main connection surface. The two housing walls are produced at an angle, for example, so that the guide surface has a desired inclination. For this purpose, a plastic can be formed into the desired shape by injection molding, for example.

The method according to a further step may further comprise Providing a base body with a base body housing and with a connection arrangement, wherein the connection arrangement is electrically connected to the main and secondary connections in order to provide an electrical connection between the connected functional modules.

The method according to a further step may further comprise Providing electrical lines of the connection arrangement arranged in the base body housing to provide a main energy flow and/or an auxiliary energy flow and/or a data flow for the connected functional modules to operate the automation platform for controlling electrical devices of an industrial plant.

The method according to the invention thus has the same advantages as those described in detail with reference to a connecting device according to the invention.

Another object of the invention is a functional module for providing at least one function for an electrical system/plant. The functional module can be designed to provide a decentralized automation platform with a connection device according to the invention, and in particular be designed to be connected to the connection device according to the invention. The functional module can comprise a connector arrangement which has a main functional module connector and/or a secondary functional module connector, wherein the main functional module connector can be designed to make contact with one of the main connections of the connection device, and wherein the secondary functional module connector can be designed to make contact with one of the secondary connections of the connection device.

Further advantages, features and details of the invention are apparent from the following description, in which embodiments of the invention are described in detail with reference to the drawings.

### BRIEF DESCRIPTION OF THE DRAWINGS

The features mentioned in the claims and in the description may each be essential to the invention individually or in any combination. It shows:

FIG. 1 a perspective view of a connecting device according to embodiments of the invention.

FIG. 2 a schematic representation of a connection arrangement.

FIG. 3 a further schematic representation of a connecting device according to embodiments of the invention.

FIG. 4 a further schematic representation of a connecting device according to embodiments of the invention.

FIG. 5 a further schematic representation of a connecting device according to embodiments of the invention.

FIG. 6 a visualization of a method according to embodiments of the invention.

In the following figures, the identical reference symbols are used for the same technical features, even for different embodiments.

### DETAILED DESCRIPTION

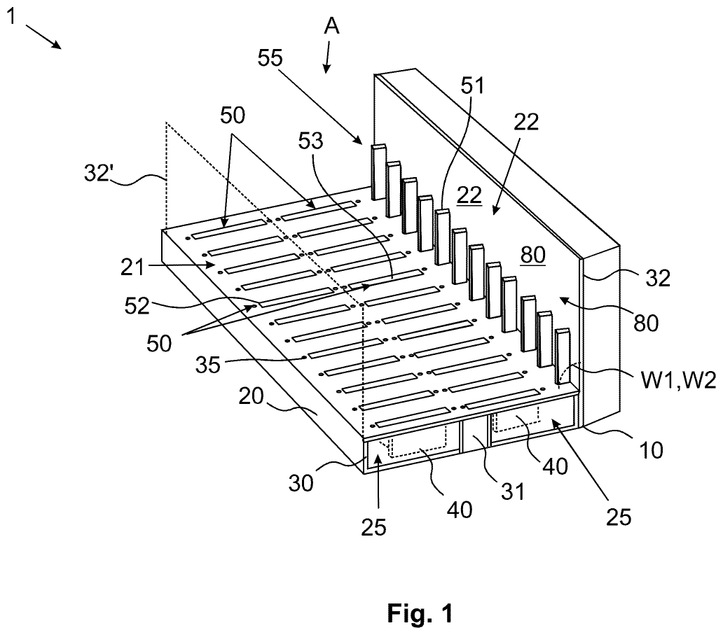

FIG. 1 illustrates a connection device 10 according to embodiments of the invention for providing a decentralized automation platform 1. An arrangement of several main and secondary connections 50, 55 is shown, which are provided for the electrical connection of several functional modules 200 in a connection area A of the connection device 10. Furthermore, a main connection surface 21 is shown, on which at least the main connections 50 are arranged. In the present example, the main connection surface 21 is formed by a housing wall which has a grid of several openings for the main connections 50. The openings can be formed in the housing wall, for example, by milling or punching corresponding recesses into the material. Alternatively, the openings can also be cut into the housing using laser technology. Electronics can be provided below the housing wall, in particular at least one printed circuit board and/or the main connections 50 in the form of electrical plug connections. The main connections 50 can optionally protrude through the openings.

A first guide surface 80 of a first guide wall 32 and a further optional guide surface (dashed line) of a second guide wall 32′ are also shown, which are each arranged at a defined angle W1 to the respective main connection surface 21. This enables the functional modules 200 to be mechanically guided into the connection area A and thus supports an assembly of the functional modules 200, which is provided for connection to the main and/or secondary connections 50,55. Furthermore, a base body 20 with a base body housing 30 is shown. If only one first guide surface 80 is used, the base body housing 30 can form an L-shape and, if guide surfaces 32, 32′ are arranged opposite one another, a U-shape.

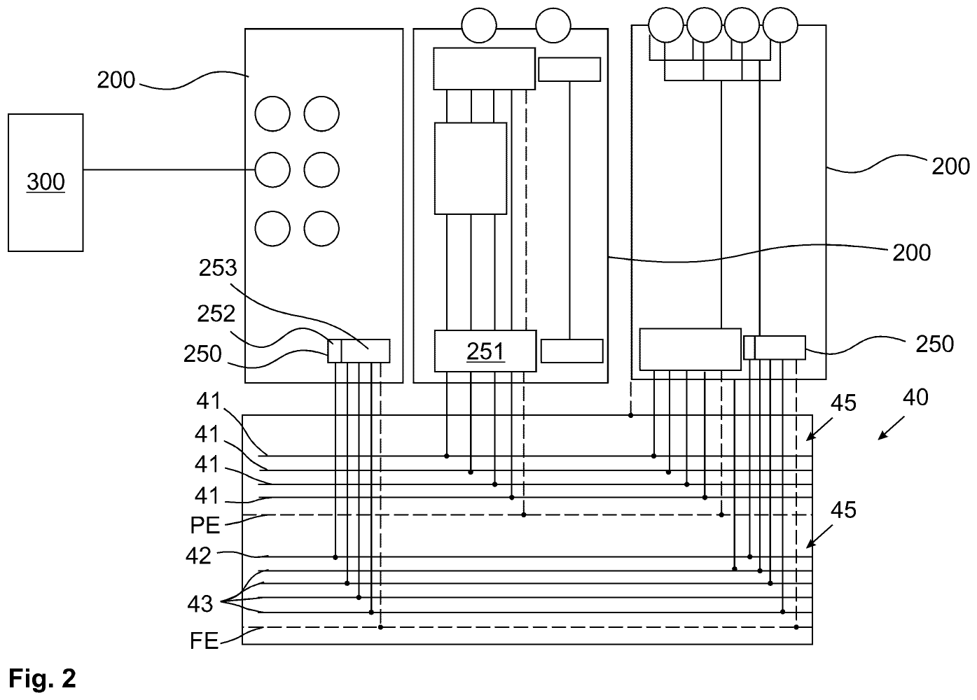

A connection arrangement 40, which is electrically connected to the main and secondary connections 50, 55, can be arranged inside the main body housing 30. The electrical lines 45 of the connection arrangement 40, shown schematically in FIG. 2, can be accommodated in the base body housing 30 so as to be electrically insulated from the outside. They serve to provide a main energy flow and/or an auxiliary energy flow and/or a data flow for the connected functional modules 200 in order to operate the automation platform 1 in this way for controlling electrical devices 300 of an industrial system/plant.

As can be clearly seen in FIG. 1, the main connections 50 can be arranged in a grid at equal distances from one another in order to receive and hold one of the functional modules 200 in a predefined position in each case. Deviating from this, it is also possible for the main connections 50 to be arranged at irregular intervals. In this case, the main connections 50 can each have at least two of the following connection elements 51, 52, 53: a main power connection element 51 for providing the main energy flow for the functional module 200 connected thereto, an auxiliary (secondary) power connection element 52 for providing the auxiliary energy flow for the functional module 200 connected thereto, with a lower electrical voltage than the main energy flow, a data connection element 53 for providing the data flow for the functional module 200 connected thereto. It is preferred that the main connections 50 each have the auxiliary power connection element 52 and the data connection element 53, with the secondary connections 55 each having the main power connection element 51. The electrical lines 45 of the connection arrangement 40 within the main body housing 30 can be electrically connected partly to the secondary connections 55 and partly to the main connections 50.

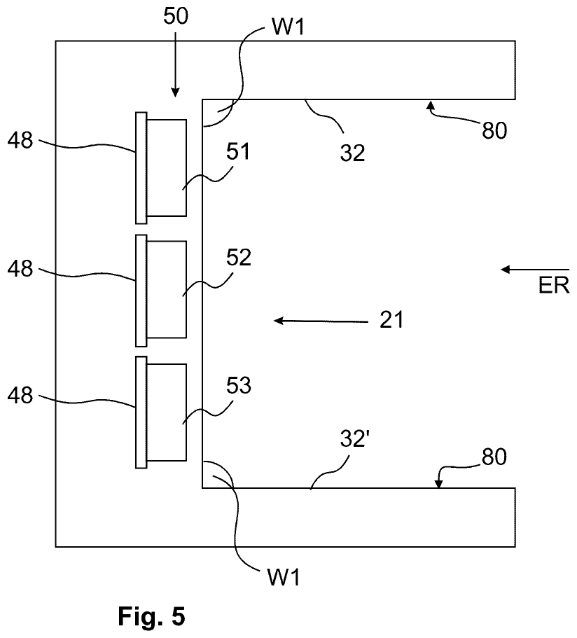

As shown in FIG. 1 and FIGS. 3 and 4, the connecting device 10 can have several or exactly one secondary connection surface 22, which is arranged at a further defined angle W2 to the respective main connection surface 21, and on which the secondary connections 55 are arranged. According to FIGS. 1 to 4, it is possible that the secondary connections 55 are arranged on the at least one guide surface 80. In FIG. 5, on the other hand, the secondary connections 55 are also provided on the main connection surface 21.

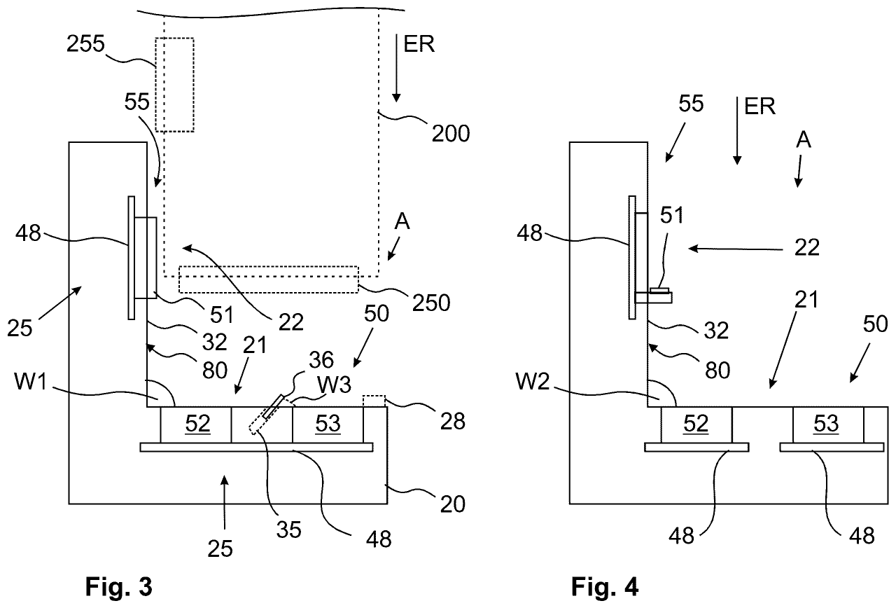

The secondary connections 55 can be oriented differently in relation to the main connections 50 (see FIG. 3), so that during assembly mechanical and/or electrical contact is made between the functional module 200 and the main and secondary connections 55 from different directions, preferably in more than one axis. Here, the at least one guide surface 80 can provide a mechanical guide in a insertion direction ER and/or in a horizontal direction (perpendicular to the direction ER) of the connecting device 10 in order to support the contacting with the main connections 50 in the insertion direction ER. Furthermore, the guide surface 80 can preferably limit a movement of the functional modules 200 during assembly in a direction deviating from the direction of insertion ER. This can have the advantage that the assembly of the functional modules 200 is simplified and incorrect assembly is avoided. It is also possible that by limiting the movement of the functional modules 200, greater precision is achieved during assembly.

Referring to FIG. 2, the electrical lines 45 of the connection arrangement 40 may comprise the following lines 45: a) main power lines 41 configured to provide the main energy flow with an AC voltage up to 1000 volts and/or a DC voltage up to 1500 volts and/or with an AC voltage in the range of 70 volts to 1000 volts and/or with a DC voltage in the range of 130 volts to 1500 volts, and preferably with an AC voltage of substantially 400 volts or a DC voltage in the range of 650 V to 700 V, preferably to supply power to at least one of the electrical devices 300. b) Auxiliary power lines 42 adapted to provide the auxiliary energy flow with an AC voltage up to 50 volts and/or a DC voltage up to 120 volts and/or with an AC voltage in the range from 0.01 volts to 50 volts and/or with a DC voltage in the range from 0.01 volts to 120 volts, and preferably with a DC voltage of substantially 24 V or 48 V, preferably to provide a power supply for at least one of the functional modules 200 and/or for a communication with at least one of the electrical devices 300, preferably for a field bus. c) Data lines 43, which are designed to transmit a data signal and preferably a fieldbus signal, preferably for communication with at least one of the electrical devices 300.

FIG. 2 further shows functional module main power connectors 251, functional module auxiliary power connectors 252 and functional module data connectors 253 of the functional modules 200. Here, the connectors 251,252,253 serve to be electrically connected to the corresponding connecting elements 51,52,53 of the main connections 50 and secondary connections 55 in order to tap the corresponding main and/or auxiliary energy flow and/or data flow. The functional modules 200 can in each case only have the connectors 251,252,253 if they actually require the corresponding energy and/or data flow.

According to FIGS. 1, 3 and 4, the main power lines 41 and/or the auxiliary power lines 42 and/or data lines 43 may be arranged in separate channels 25 of the base body 20 and preferably separated from each other by a partition 31. This can have the advantage that the lines are protected from external influences, which increases the stability and reliability of the system/plant. It is also possible that the separate arrangement of the lines enables easier maintenance and repair of the system/plant, as the lines are more easily accessible. The partition 31 may be made of an insulating material to prevent interference between the lines.

FIGS. 1 and 3 to 5 show that the defined angle W1 and preferably also the further defined angle W2 can be substantially 90 degrees, with the respective guide surfaces 80 being connected to the one or at least one of the main connection surfaces 21 and representing an extension of the respective main connection surface 21. Further possible ranges for the angle W1 are 80 to 100 degrees and for the angle W2 are 80 to 110 degrees. The fixed connection of the guide surfaces 80 to the main connection surfaces 21 can also create a particularly robust and durable connection.

It is clear from FIGS. 3 and 4 that contact can be made in more than one axis between a connector arrangement 250, 255 of one of the functional modules 200, comprising a functional module main connector 250 and a functional module secondary connector 255, and a connection arrangement 50, 55 of the base body 20, comprising one of the main connections 50 and one of the secondary connections 55. It can also be seen that, according to embodiments of the invention, the base body housing 30 forms the respective main connection surface 21 and guide surface 80 and, in particular, the secondary connection surface 22. The base body housing 30 can be essentially L-shaped (see FIGS. 1, 3 and 4) or U-shaped (see FIGS. 1 and 5), with the parts of the base body housing 30 being connected to one another in a form-fitting and/or force-fitting manner.

In the sectional view in FIG. 3, at least one sealing means 28 is shown schematically in the connection area A in order to seal the connection area A. It is also shown that at least one receptacle 35 can be provided for a fastening element 36, preferably for a screw, wherein the receptacle 35, preferably a threaded hole, is formed with an angle W3, preferably in the range from 10° to 80°, to the main connection surface 21 in the base body housing 30 in order to provide an angled fastening and preferably screw connection of the respective functional module 200 to the base body housing 30.

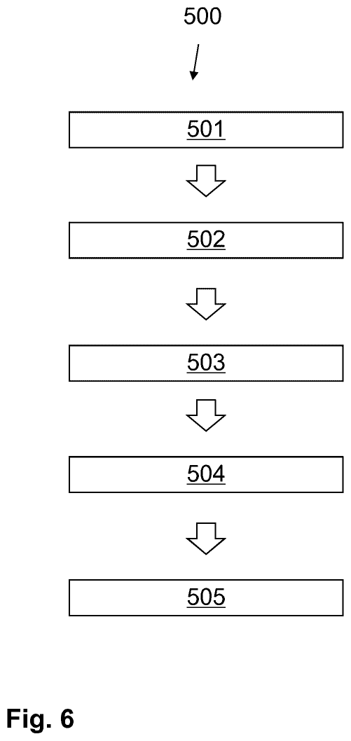

In FIG. 6, a method 500 for operating a connection device 10 for providing a decentralized automation platform 1 is schematically visualized. According to a first method step 501, an arrangement of a plurality of main and secondary connections 50, 55 is provided, which are provided for the electrical connection of a plurality of functional modules 200 in a connection area A of the connection device 10. According to a second method step 502, an arrangement of several or exactly one main connection surface 21 is provided, on which at least the main connections 50 are arranged. According to a third method step 503, at least one guide surface 80 is provided, which is arranged at a defined angle W1 to the respective main connection surface 21 in order to mechanically guide the functional modules 200 into the connection area A and thus support assembly of the functional modules 200, which is provided for connection to the main and/or secondary connections 50, 55. The assembly can be carried out, for example, by placing the functional modules 200 on the guide surface 80 and then manually moving them in the direction of the main connection surface 21 until they fit into the connection area A. According to a fourth method step 504, a base body 20 is provided with a base body housing 30 and with a connection arrangement 40, wherein the connection arrangement 40 is electrically connected to the main and secondary connections 50, 55 in order to provide an electrical connection between the connected functional modules 200. According to a fifth method step 505, electrical lines 45 of the connection arrangement 40, which are arranged in the base body housing 30, are provided in order to provide a main energy flow, an auxiliary energy flow and a data flow for the connected functional modules 200 in order to operate the automation platform 1 for controlling electrical devices 300 of an industrial plant.

The foregoing explanation of the embodiments describes the present invention solely by way of examples. Of course, individual features of the embodiments can be freely combined with one another, provided that this is technically expedient, without leaving the scope of the present invention.

### List of Reference Signs

1 Automation platform
10 Connecting device
20 Base body
21 Main connection surface
22 Shunt connection area
25 Channels
28 Sealant
30 Base body housing
31 Partition wall
32 Guide wall
35 Receptacle
36 Fastening element
40 Connection arrangement
41 Main power lines
42 Auxiliary power lines
43 Data lines
45 Cables
48 Printed circuit board
50 Main connections
51 Main energy connection element
52 Power supply connection element
53 Data link element
55 Secondary connections
80 Guide surface
200 Functional modules
250 Functional module main connector
251 Functional module main power connector
252 Functional module auxiliary power connector
253 Functional module data connector
255 Functional module auxiliary connector
300 electrical devices
32′ second guide wall
500 Method
A Connection area
ER Insertion direction
W1 Angle
W2 other defined angles
W3 further angle

1. A connection device for providing a decentralized automation platform, comprising:
an arrangement of a plurality of main and secondary connections, which are provided for the electrical connection of a plurality of functional modules in a connection area (A) of the connection device, several or exactly one main connection surface, on which at least the main connections are arranged,
at least one guide surface, which is arranged at a defined angle (W1) to the respective main connection surface, in order to mechanically guide the functional modules into the connection area (A) and thus support assembly of the functional modules, which is provided for the connection to the main and/or secondary connections,
a base body with a base body housing and with a connection arrangement, wherein the connection arrangement is electrically connected to the main and/or secondary connections in order to provide an electrical connection for at least some of the connected functional modules to one another,
electrical lines of the connection arrangement arranged in the base body housing to provide a main energy flow, an auxiliary energy flow and a data flow for the connected functional modules in order to operate the automation platform for controlling electrical devices of an industrial plant.

2. Connecting device according to claim 1,
characterized in that
in that the main connections are arranged at a distance from one another in order to each receive and hold one of the functional modules in a predefined position, the main connections each having at least two of the following connecting elements:
a main power connection element for providing the main energy flow for the functional module connected thereto,
an auxiliary power connection element for providing the auxiliary energy flow for the functional module connected thereto, with a lower electrical voltage than the main energy flow,
a data connection element for providing the data flow for the functional module connected thereto.

3. Connecting device according to claim 2,
characterized in that
in that the main connections each have the auxiliary power connection element and the data connection element, the secondary connections each having the main power connection element, the electrical lines of the connection arrangement within the main body housing being electrically connected in part to the secondary connections and in part to the main connections.

4. Connecting device according to claim 1,
characterized in that
in that the connecting device further comprises:
several or exactly one secondary connection surface, which is arranged at a further defined angle (W2) to the respective main connection surface and on which the secondary connections are arranged, and/or
in that the secondary connections are arranged on the at least one guide surface.

5. Connecting device according to claim 1,
characterized in that
in that the secondary connections are oriented differently in relation to the main connections, so that during assembly mechanical and/or electrical contact is made between the functional module and the main and secondary connections from different directions, wherein the at least one guide surface provides a mechanical guide in an insertion direction (ER) and/or in a width direction of the connecting device in order to support the contacting with the main connections in the insertion direction (ER).

6. Connecting device according to claim 1,
characterized in that
in that the electrical lines of the connection arrangement comprise the following lines:
main power lines adapted to provide the main energy flow with an AC voltage up to 1000 volts and/or with a DC voltage up to 1500 volts and/or with an AC voltage in the range of 70 volts to 1000 volts and/or with a DC voltage in the range of 130 volts to 1500 volts,
auxiliary power lines which are designed to provide the auxiliary energy flow with an AC voltage of up to 50 volts and/or with a DC voltage of up to 120 volts and/or with an AC voltage in the range from 0.01 volts to 50 volts and/or with a DC voltage in the range from 0.01 volts to 120 volts.

7. Connecting device according to claim 1,
characterized in that
in that the defined angle (W1) is substantially 90 degrees.

8. Connecting device according to claim 1,
characterized in that
in that contact is made between a connector arrangement of one of the functional modules, comprising a functional module main connector and a functional module secondary connector , and a connection arrangement of the base body, comprising one of the main connectors and one of the secondary connections, in more than one axis.

9. Connecting device according to claim 1,
characterized in that
in that the basic body housing is designed in several parts and forms the respective main connection surface and guide surface, the basic body housing being essentially L-shaped or U-shaped, the parts of the basic body housing being connected to one another in a form-fitting and/or force-fitting manner.

10. Connecting device according to claim 1,
characterized in that
in that the base body housing is formed in one piece and forms the respective main connection surface and guide surface and, the base body housing being essentially L-shaped or U-shaped.

11. Connecting device according to claim 1,
characterized in that
that at least one sealing means is provided in the connection area (A) in order to seal the connection area (A).

12. Connecting device according to claim 1,
characterized in that
in that at least one receptacle for a fastening element, is provided, the receptacle, being formed with an angle (W3) to the main connection surface in the basic body housing, in order to provide an angled fastening.

13. An automation platform, comprising:
at least one connecting device, the connecting device comprising:
an arrangement of a plurality of main and secondary connections, which are provided for the electrical connection of a plurality of functional modules in a connection area (A) of the connection device.
several or exactly one main connection surface, on which at least the main connections are arranged,
at least one guide surface, which is arranged at a defined angle (W1) to the respective main connection surface, in order to mechanically guide the functional modules into the connection area (A) and thus support assembly of the functional modules, which is provided for the connection to the main and/or secondary connections.
a base body with a base body housing and with a connection arrangement, wherein the connection arrangement is electrically connected to the main and/or secondary connections in order to provide an electrical connection for at least some of the connected functional modules to one another, and
electrical lines of the connection arrangement arranged in the base body housing to provide a main energy flow, an auxiliary energy flow and a data flow for the connected functional modules in order to operate the automation platform for controlling electrical devices of an industrial plant.

14. Method for operating a connection device for providing a decentralized automation platform, wherein the following steps are provided:
Providing an arrangement of a plurality of main and auxiliary terminals which are provided for the electrical connection of a plurality of functional modules in a connection area (A) of the connection device,
Provision of several or exactly one main connection surface, on which at least the main connections are arranged,
Provision of at least one guide surface, which is arranged at a defined angle (W1) to the respective main connection surface, in order to mechanically guide the functional modules into the connection area (A) and thus support assembly of the functional modules, which is provided for connection to the main and/or secondary connections,
Provision of a base body with a base body housing and with a connection arrangement, the connection arrangement being electrically connected to the main and/or secondary connections in order to provide an electrical connection for at least some of the connected functional modules to one another,
Providing electrical lines of the connection arrangement arranged in the base body housing to provide a main energy flow, an auxiliary energy flow and a data flow for the connected functional modules in order to operate the automation platform for controlling electrical devices of an industrial plant.

15. The connecting device of claim 1 further comprising:
a functional module for providing at least one function for an electrical plant, wherein the functional module comprises a connector arrangement which has a functional module main connector and a functional module secondary connector, wherein the functional module main connector is designed to make contact with one of the main connections of the connection device, and wherein the functional module secondary connector is designed to make contact with one of the secondary connections of the connection device.

16. The connecting device of claim 5, wherein at least one of:
(a) the one or more directions comprise different directions in more than one axis; and/or
(b) wherein the guide surface limits a movement of the functional modules during assembly in a direction deviating from the insertion direction (ER).

17. The connecting device of claim 6, wherein at least one of:
(a) wherein the main power lines provide the main energy flow with the AC voltage of substantially 400 volts and/or the DC voltage in the range of 650 V to 700 V;
(b) wherein the main power lines are adapted to provide the main energy flow to supply power to at least one of the electrical devices;
(c) wherein the auxiliary power lines provide the auxiliary energy flow with the DC voltage being essentially 24 V or 48 V;
(d) wherein the auxiliary power lines are designed to provide a power supply for at least one of the functional modules and/or for communication with at least one of the electrical devices;
(e) wherein the auxiliary power lines are designed to provide a power supply for at least one of the functional modules and/or for communication with at least one of the electrical devices;
(f) wherein the power supply is for communication with at least one of the electrical devices is for a field bus;
(g) wherein the data lines are designed to transmit a field buss signal;
(h) wherein the data lines is for communication with at least one of the electrical devices; and/or
(i) wherein it is provided that the main power lines and the auxiliary power lines and/or the data lines are arranged in separate channels of the base body and are separated from one another by a partition wall.

18. The connecting device of claim 7, wherein at least one of:
(a) wherein the further defined angle is substantially 90 degrees; and/or
(b) wherein the respective guide surface is connected to the one or at least one of the main connection surfaces and represents an extension of the respective main connection surface.

19. The connecting device of claim 9, wherein at least one of:
(a) wherein the secondary surface comprises the guide surface.

20. The connecting device of claim 12, wherein at least one of:
(b) wherein the fastening element is a screw;
(c) wherein the receptacle is a threaded hole;
(d) wherein the angle is in the range from 10° to 80°; and/or
(e) wherein the angled fastening is a screw connection of the respective functional module to the basic body housing.
